(19) United States
(12) Patent Application Publication
(10) Pub. No.: US 2026/0191050 A1
(43) Pub. Date: Jul. 2, 2026

(54) PLATED MAGNETIC VIA FOR GLASS CORE

(71) Applicant: Intel Corporation, Santa Clara, CA (US)

(72) Inventors: Brandon C. MARIN, Gilbert, AZ (US); Srinivas Venkata Ramanuja PIETAMBARAM, Chandler, AZ (US); Sashi S. KANDANUR, Phoenix, AZ (US); Gang DUAN, Chandler, AZ (US); Jeremy D. ECTON, Gilbert, AZ (US)

(21) Appl. No.: 19/003,818

(22) Filed: Dec. 27, 2024

(51) Int. Cl. H01L 23/498; H01L 21/48; H01L 23/15; H01L 23/64

(52) U.S. Cl. CPC H10W 70/65; H10W 44/501; H10W 70/095; H10W 70/635; H10W 70/66; H10W 70/692

(57) ABSTRACT

Embodiments disclosed herein include an apparatus that includes a substrate that comprises a glass layer. In an embodiment, an opening is provide through a thickness of the substrate, and a layer is over a sidewall of the opening. In an embodiment, the layer comprises a magnetic material, and a via is in the opening. In an embodiment, the via directly contacts the layer at a first location, and a gap is provided between the via and the layer at a second location. In an embodiment, the via is electrically conductive.

### BACKGROUND

Glass cores for package substrates are an attractive option due to the increased stiffness and planarity that they provide compared to existing organic cores. However, the brittle nature of glass provides several challenges with respect to manufacturing. One issue that is present for glass cores is the high stress that is generated by vias that are formed through the glass core (i.e., through glass vias (TGVs)). With traditional plating, a seed layer is provided along the sidewalls of the via opening, and the via is plated out from the sidewalls. This provides a strong mechanical coupling between the vias and the glass core. During thermal cycling, the via expands more than the glass core, and this generates a high stress in the glass core. The high stress may result in cracking or other defects that significantly impact the reliability of the glass core.

### BRIEF DESCRIPTION OF THE DRAWINGS

FIG. 1A is a cross-sectional illustration of a plated magnetic via through a glass core, in accordance with an embodiment.

FIG. 1B is a cross-sectional illustration of a plurality of plated magnetic vias electrically coupled to each other in series, in accordance with an embodiment.

FIGS. 2A-2G are cross-sectional illustrations that depict a process for forming a plated magnetic via with a bottom-up process, in accordance with an embodiment.

FIGS. 3A-3H are cross-sectional illustrations that depict a process for forming a package substrate with a glass core that includes plated magnetic vias that are formed with a bottom-up process, in accordance with an embodiment.

FIG. 4 is a flow diagram of a process for forming a plated magnetic via in a glass core with a bottom-up process, in accordance with an embodiment.

FIG. 5 is a cross-sectional illustration of an electronic system that comprises a package substrate with a glass core that includes a plated magnetic via that is formed with a bottom-up process, in accordance with an embodiment.

FIG. 6 is a schematic of a computing device built in accordance with an embodiment.

### EMBODIMENTS OF THE PRESENT DISCLOSURE

Described herein are glass substrates with plated magnetic vias (PMVs) that are formed with a bottom-up process, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, existing glass cores provide stiffness and/or improved planarity compared to organic cores. However, the strong mechanical coupling between the through glass vias (TGVs) and the glass core results in significant stress being induced in the glass core during thermal cycling. As such, cracking or other damage to the glass core may occur. This negatively impacts the reliability of such glass cores. Further, the high aspect ratios of the TGVs make it difficult to form void-free TGVs in a cost-effective manner. For example, an atomic layer deposition process may be used. However, atomic layer deposition is a slow and expensive process, and such a process may not be compatible with high volume manufacturing environments.

In some instances, inductive structures are integrated into circuitry of the package substrate. For example, inductors may be used in voltage regulators. Space savings can be obtained when the inductors are integrated into the core of the package substrate. Inductors within the core may be vertically oriented, such as magnetic coaxial structures. Magnetic coaxial structures may include a magnetic shell that surrounds an electrically conductive via through the core. Such integrated solutions have been shown to handle significantly higher current densities compared to previous magnetic inductor arrays (MIA) or air core inductors (ACI). This enhances reliability and performance in high core count architectures.

However, previous magnetic coaxial structures were fabricated in organic cores. As noted above, reliability concerns may be present when implementing such magnetic coaxial structures are formed in a glass core. That is, plating up the electrically conductive via from the sidewalls of the via opening may result in high stresses that can lead to cracking and/or other damage to the glass core.

Accordingly, embodiments disclosed herein include a bottom-up plating process in order to form magnetic coaxial structures, such as a plated magnetic via (PMV). In a bottom-up plating process, an electrically conductive layer is provided across a bottom of the via opening after the magnetic layer is formed along the sidewalls of the via opening. The plating proceeds in a vertical direction up through the via opening and within the shell of the magnetic layer. In such an embodiment, the interface between the via and the sidewall of the magnetic layer has a weaker mechanical coupling than traditional plating from a seed layer along the sidewall of the magnetic layer. For example, the via may have a sidewall that contacts the sidewall of the magnetic layer in some locations and is spaced away from the sidewall of the magnetic layer by gaps (e.g., air gaps) at other locations. The gaps may have a width between the sidewall of the magnetic layer and the via that are in the submicron scale. As such, the electrical conductivity is not significantly impacted while also allowing for improved mechanical reliability of the glass core.

In some embodiments, the conductive layer below the via opening may be supported by a carrier. In some embodiments, the carrier may be coupled to the glass core by the conductive layer. For example, the conductive layer may be a conductive adhesive. In some instances, the conductive adhesive may also comprise an underlying conductive seed layer (e.g., comprising titanium and/or copper) to improve the electrical conductivity of the conductive adhesive in order to improve the plating process.

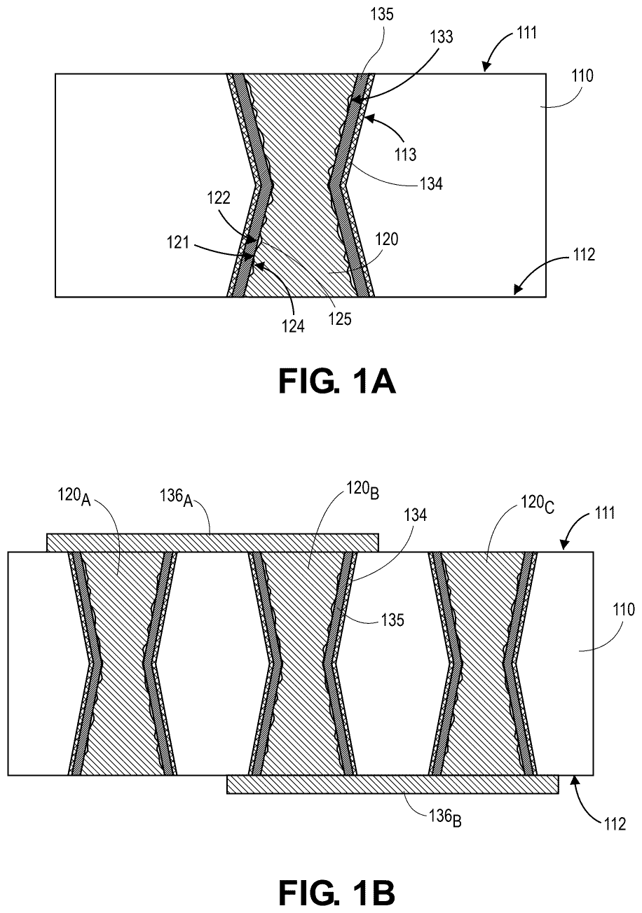

Referring now to FIG. 1A, a cross-sectional illustration of a glass core 110 with a PMV structure through an opening that passes from a first surface 111 to a second surface 112 is shown, in accordance with an embodiment. In an embodiment, the PMV structure may comprise a via 120 that is surrounded by a magnetic layer 135. The via 120 and the magnetic layer may at least partially fill an opening through the glass core 110 that is defined by sidewall 113. In the illustrated embodiment, the sidewall 113 may be sloped. For example, the sidewall 113 in FIG. 1A defines an hourglass shaped via opening. Though, in other embodiments, the sidewalls 113 may have any suitable profile, depending on the process used to form the opening through glass core 110.

In an embodiment, the magnetic layer 135 may be plated up from a seed layer 134 that is provided on the sidewall 113. The seed layer 134 may include any suitable conductive material. For example, the seed layer 134 may comprise ruthenium or a ruthenium oxide. In an embodiment, the magnetic layer 135 may include any suitable magnetic material. For example, the magnetic layer 135 may comprise one or more of iron, cobalt, nickel, or the like.

In an embodiment, the via 120 is formed with a bottom-up plating process. The bottom-up plating process will be described in greater detail below. The bottom-up plating process may result in the formation of gaps 125 between a sidewall 124 of the via 120 and the sidewall 133 of the magnetic layer 135. However, there may also be positions through the height of the via 120 where the sidewall 124 directly contacts the sidewall 133 of the magnetic layer 135. For example, the sidewall 124 of the via 120 may contact the sidewall 133 of the magnetic layer 135 at a first location 121, and a sidewall 124 is spaced away from the sidewall 133 of the magnetic layer 135 by a gap 125 at a second location 122. In an embodiment, the gap 125 may have a width that is approximately 1 micron or less, approximately 500 nm or less, approximately 100 nm or less, or approximately 50 nm or less. In contrast, a via 120 that is plated out from the sidewall 133 of the magnetic layer 135 may not have a discernable gap 125 between the via 120 and the magnetic layer 135.

Referring now to FIG. 1B, a cross-sectional illustration of a glass core 110 is shown, in accordance with an additional embodiment. As shown, a plurality of PMVs are provided within the glass core 110. In some embodiments, the vias 120_{A}, 120_{B}, and 120_{C} may be electrically coupled to each other by traces 136_{A} and 136_{B} provided on the first surface 111 and the second surface 112, respectively. Electrically coupling the vias 120_{A}-120_{C} in series may allow for a higher inductance value to be provided to a circuit. While three PMVs are electrically coupled in series in FIG. 1B, it is to be appreciated that any number of PMVs may be electrically coupled in series to provide a desired level of inductance.

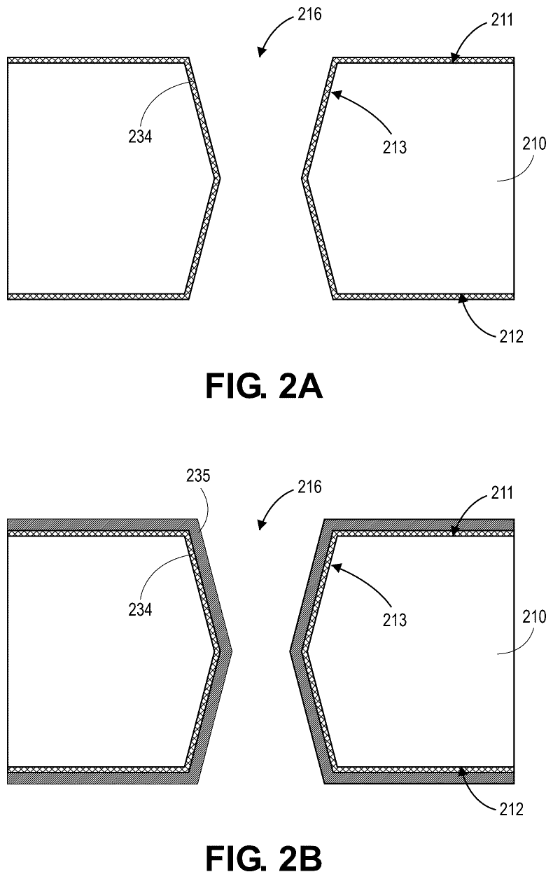

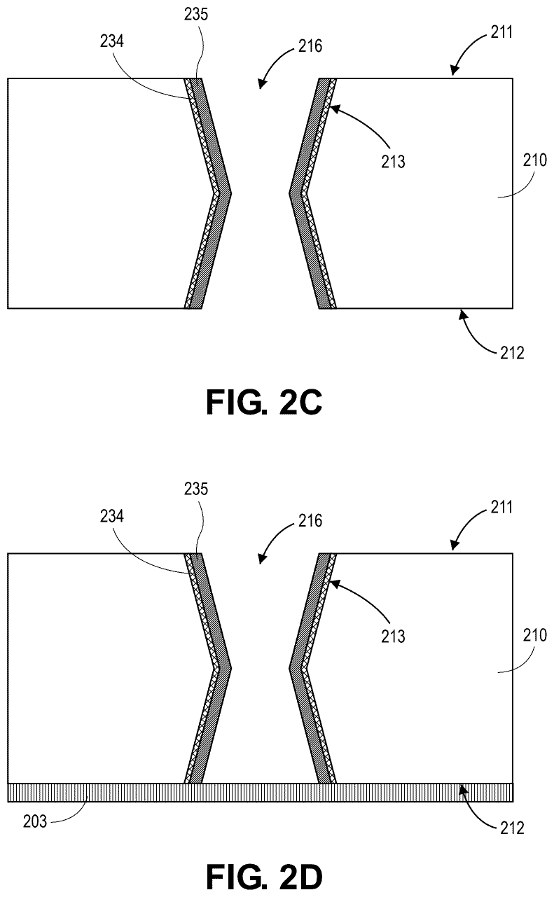

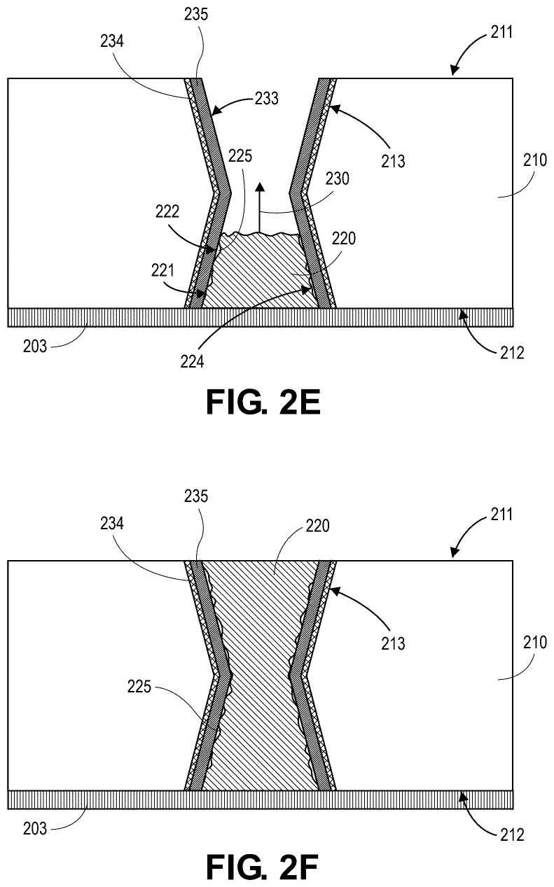

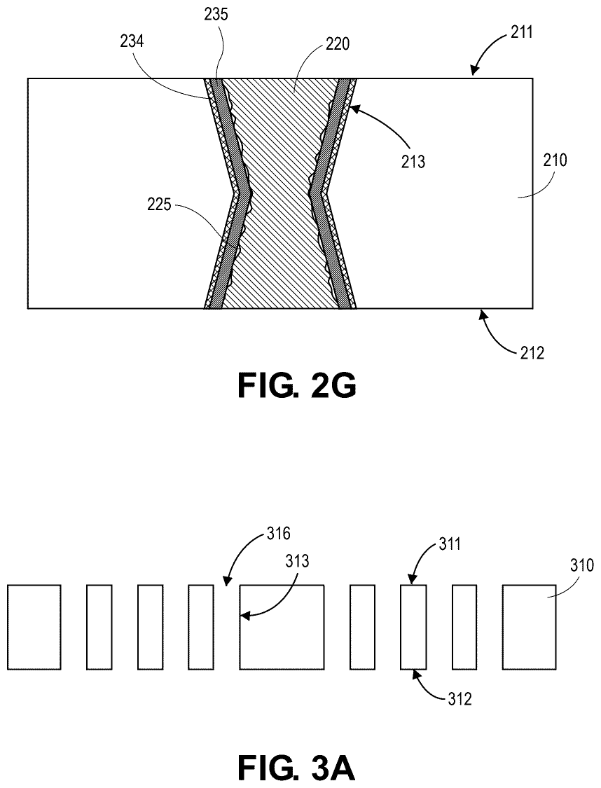

Referring now to FIGS. 2A-2G , a series of cross-sectional illustrations depicting a process for forming a PMV in a glass core with a bottom-up plating process is shown, in accordance with an embodiment.

Referring now to FIG. 2A, a cross-sectional illustration of a glass core 210 is shown, in accordance with an embodiment. In an embodiment, a via opening 216 is provided through a thickness of the glass core 210. The via opening 216 may be formed with any suitable process. For example, a laser assisted etching process may be used to form the via opening 216 in some embodiments. In an embodiment, the via opening 216 may be a high aspect ratio via opening 216. For example, an aspect ratio (height:width) of the via opening 216 may be 5:1 or greater, 10:1 or greater, or 20:1 or greater. Though, embodiments may also be used with smaller aspect ratio via openings 216 as well.

In the illustrated embodiment, sidewalls 213 of the via opening 216 have a slope relative to a top surface 211 and a bottom surface 212 of the glass core 210. The via opening 216 may have sidewalls 213 that form an hourglass shape. Though, in other embodiments, the sidewalls 213 may have a single slope to form a via opening 216 with a single taper. In other embodiments, the sidewalls 213 may be substantially vertical (i.e., orthogonal to the top surface 211), the sidewalls 213 may be curved (e.g., non-planar), or have any other suitable profile.

In an embodiment, the glass core 210 may be substantially all glass. The glass core 210 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, glass core 210 may be distinguished from, for example, the “prepreg” or “FR4” core of a Printed Circuit Board (PCB) substrate which typically comprises glass fibers embedded in a resinous organic material, such as an epoxy.

The glass core 210 may have any suitable dimensions. In a particular embodiment, the glass core 210 may have a thickness that is approximately 50 μm or greater. For example, the thickness of the glass core 210 may be between approximately 50 μm and approximately 1.4 mm. Though, smaller or larger thicknesses may also be used. The glass core 210 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the glass core 210 (from an overhead plan view) may be between approximately 10 mm×10 mm and approximately 250 mm×250 mm. In an embodiment, the glass core 210 may have a first side that is perpendicular or orthogonal to a second side. In a more general embodiment, the glass core 210 may comprise a rectangular prism volume with sections (e.g., vias) removed and filled with other materials (e.g., metal, etc.).

The glass core 210 may comprise a single monolithic layer of glass. In other embodiments, the glass core 210 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core 210 may each have a thickness less than approximately 50 μm. For example, discrete layers of glass in the glass core 210 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass core 210 may be any suitable glass formulation that has the necessary mechanical robustness and compatibility with semiconductor packaging manufacturing and assembly processes. For example, the glass core 210 may comprise aluminosilicate glass, borosilicate glass, alumino-borosilicate glass, silica, fused silica, or the like. In some embodiments, the glass core 210 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core 210 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core 210 may comprise at least 23 percent silicon (by weight) and at least 26 percent oxygen (by weight). In some embodiments, the glass core 210 may further comprise at least 5 percent aluminum (by weight).

In an embodiment, a seed layer 234 may be formed over the sidewall 213 of the via opening 216, the top surface 211, and the bottom surface 212 of the glass core 210. In an embodiment, the seed layer 234 may include an electrically conductive material, such as ruthenium or a ruthenium oxide.

Referring now to FIG. 2B, a cross-sectional illustration of the glass core 210 after a magnetic layer 235 is formed over the seed layer 234 is shown, in accordance with an embodiment. In an embodiment, the magnetic layer 235 may be plated up from the seed layer with any suitable process. Since the magnetic layer 235 does not fully fill the via opening 216, the stresses induced into the glass core 210 are less than when a via is plated up to fully fill the via opening 216. In an embodiment, the magnetic layer 235 may comprise any suitable magnetic material, such as one or more of iron, cobalt, nickel, or the like.

Referring now to FIG. 2C, a cross-sectional illustration of the glass core 210 after portions of the seed layer 234 and the magnetic layer 235 are removed from the top surface 211 and the bottom surface 212 of the glass core 210 is shown, in accordance with an embodiment. In an embodiment, the portions of the seed layer 234 and the magnetic layer 235 may be removed with an etching process, a polishing process, or any other suitable subtractive process.

Referring now to FIG. 2D, a cross-sectional illustration of the glass core 210 after a conductive layer 203 is provided on the bottom surface 212 of the glass core 210 is shown, in accordance with an embodiment. The conductive layer 203 may comprise a metallic material (e.g., titanium and/or copper). As will be described in greater detail herein, the conductive layer 203 may also be a conductive adhesive layer in order to couple the glass core 210 to a carrier substrate (not shown in FIG. 2A). The conductive layer 203 may span across the via opening 216. As such, a portion of the conductive layer 203 is exposed by the via opening 216 in order to allow for the bottom-up plating process described in greater detail herein.

Referring now to FIG. 2E, a cross-sectional illustration of the glass core 210 after a portion of the via 220 is plated is shown, in accordance with an embodiment. As indicated by the arrow 230, the plating of the via 220 extends in a vertical direction from the conductive layer 203 in a bottom-up manner. The plating may be any suitable electroplating process. Due to the bottom-up plating process, the sidewalls 224 of the via 220 may have a textured surface that interfaces with the sidewall 233 of the magnetic layer 235. For example, the sidewalls 224 may be non-linear with peaks and valleys. In an embodiment, the sidewall 224 of the via 220 may directly contact the sidewall 233 of the magnetic layer 235 at a first location 221, and the sidewall 224 of the via 220 may be spaced away from the sidewall 233 of the magnetic layer 235 by a gap 225 at a second location 222.

In an embodiment, the via 220 directly contacting the sidewall 233 of the magnetic layer 235 may refer to there being no intermediary layer between the via 220 and the sidewall 233. For example, in existing plating processes, a seed layer or the like may be provided between the sidewall 233 of the magnetic layer 235 and the sidewall 224 of the via 220. In an embodiment, the gap 225 may have any suitable dimension. For example, a width of the gap 225 between the sidewall 233 of the magnetic layer 235 and the sidewall 224 of the via 220 may be up to approximately 5 μm, up to approximately 1 μm, up to approximately 0.5 μm, or up to approximately 0.1 μm. As noted above, the presence of the gaps 225 allows for weaker mechanical coupling between the via 220, the magnetic layer 235, and ultimately, the glass core 210. Accordingly, stress related to coefficient of thermal expansion (CTE) mismatch between the glass core 210 and the via 220 may be mitigated, and the mechanical robustness of the glass core 210 is improved.

Referring now to FIG. 2F, a cross-sectional illustration of the glass core 210 after the plating of the via 220 is completed is shown, in accordance with an embodiment. As shown, the via 220 substantially fills the via opening within the magnetic layer 235, with the exception of the presence of gaps 225 at some locations along the height of the via 220. In a particular embodiment, a cross-sectional area of the via 220 along a plane (e.g., the plane illustrated in FIG. 2F) may be smaller than a cross-sectional area of a portion of the via opening surrounded by the magnetic layer 235 along the same plane. In an embodiment, the difference between the cross-sectional areas of the portion of the via opening surrounded by the magnetic layer 235 and the via 220 may be occupied by the cross-sectional area of all of the gaps 225. In an embodiment, the cross-sectional area of the via 220 along the plane may be approximately 95% or more of the cross-sectional area of the portion of the via opening surrounded by the magnetic layer 235, approximately 99% or more of the cross-sectional area of the portion of the via opening surrounded by the magnetic layer 235, approximately 99.5% or more of the cross-sectional area of the portion of the via opening surrounded by the magnetic layer 235, or approximately 99.9% or more of the cross-sectional area of the portion of the via opening surrounded by the magnetic layer 235.

In an embodiment, the via 220 may comprise a substantially uniform composition across a line from a first edge of the via 220 to a second edge of the via 220 that is parallel to the top surface 211 or the bottom surface 212 of the glass core 210. For example, the via 220 may have a substantially uniform composition comprising copper. This is different than many existing via architectures that include a seed layer along the sidewall of the magnetic layer 235. In such an embodiment, the via may have a different composition along the outer edge of the via due to the seed layer. For example, concentrations of titanium or other seed layer materials may be present at the edge of the via. However, embodiments disclosed herein may comprise a substantially uniform composition from edge-to-edge since a bottom-up plating process is used.

Referring now to FIG. 2G, a cross-sectional illustration of the glass core 210 after the conductive layer 203 is removed is shown, in accordance with an embodiment. In an embodiment, the conductive layer 203 may be removed with an etching process, a polishing process, or the like. Due to the presence of the conductive layer 203, the bottom surface of the via 220 may be substantially flat and coplanar with the bottom surface 212 of the glass core 210. In some embodiments, the top surface of the via 220 may be polished or planarized so that the top surface is substantially flat and coplanar with the top surface 211 of the glass core 210.

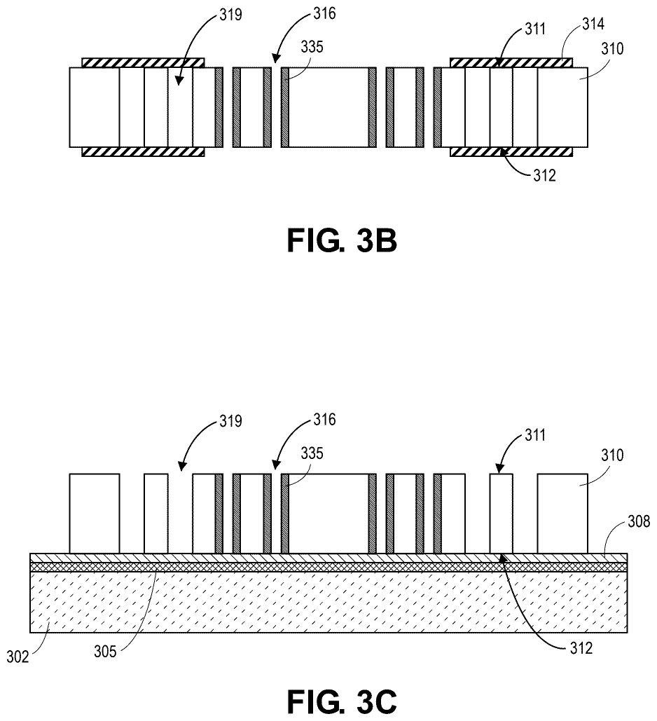

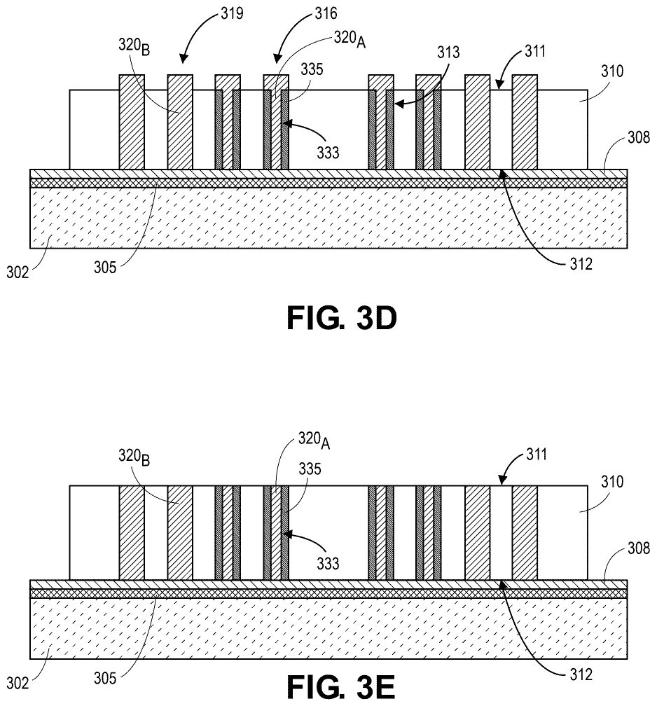

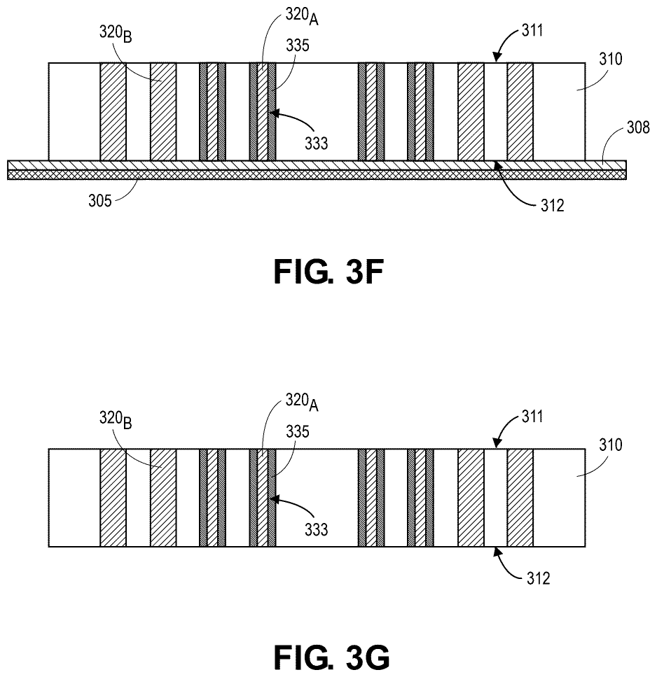

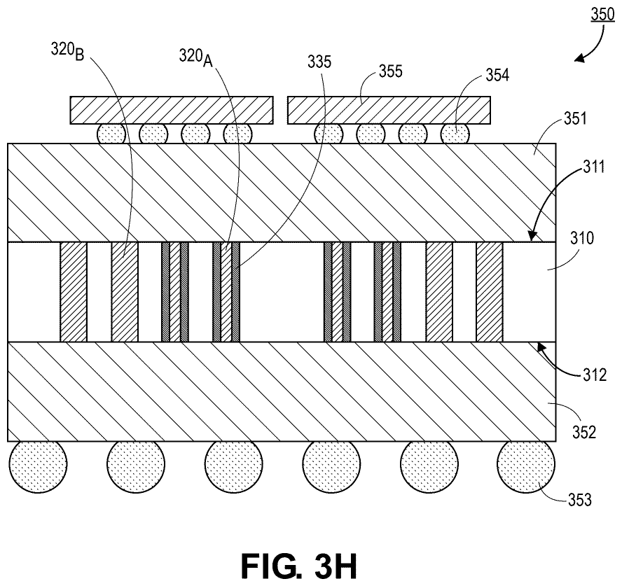

In the embodiments described above with respect to FIGS. 2A-2G , a bottom-up plating process is described in a manner that illustrates the resulting structure of the via 220 and magnetic layer 235 in order to form a PMV. That is, the composition, structure, and/or interface with the sidewall 233 of the magnetic layer 235 is described in detail. A more detailed example of how such a process may be implemented in a manufacturing setting is shown with respect to FIGS. 3A-3H . Particularly, the profile and detail of the PMV in FIGS. 2A-2G is omitted in order to direct focus to the processing and structures used to enable the bottom-up plating process. Though, it is to be appreciated that the structure, composition, and/or the like of the PMV in FIGS. 2A-2G may be similar to any of those described in greater detail herein.

Referring now to FIG. 3A, a cross-sectional illustration of a glass core 310 is shown, in accordance with an embodiment. In an embodiment, the glass core 310 may be similar to any of the glass cores or glass substrates describe in greater detail herein. In the illustrated embodiment, a single glass core 310 unit is shown. Though, it is to be appreciated that a glass panel or glass substrate with a plurality of glass core 310 units may be used in accordance with similar embodiments. In an embodiment, the glass core 310 may comprise a top surface 311 and a bottom surface 312. A plurality of via openings 316 may be formed through a thickness of the glass core 310. In the illustrated embodiment, the sidewalls 313 of the via openings 316 are substantially vertical. Though, it is to be appreciated that the sidewalls 313 may be sloped with respect to the top surface 311 or the bottom surface 312 in some embodiments. The via openings 316 may be formed with any suitable patterning process, such as a laser assisted etching process.

Referring now to FIG. 3B, a cross-sectional illustration of the glass core 310 after one or more of the via openings 316 are lined with a magnetic layer 335 is shown, in accordance with an embodiment. As shown, four of the via openings 316 are lined by a magnetic layer 335, and four via openings 316 are masked with a masking layer 314 to prevent deposition of the magnetic layer 335 into the via openings 319. In an embodiment, the magnetic layer 335 may be formed with a plating process (e.g., over a seed layer (not shown)) using a process similar to what is shown in FIGS. 2A-2C described in greater detail above.

Referring now to FIG. 3C, a cross-sectional illustration of the glass core 310 after a carrier 302 is attached to the glass core 310 is shown, in accordance with an embodiment. In an embodiment, the glass core 310 may be coupled to the carrier 302 by an electrically conductive adhesive layer 308. In an embodiment, the electrically conductive adhesive layer 308 may comprise an electrically conductive adhesive (ECA), an anisotropic conductive film (ACF), or the like. In some embodiments, the electrical conductivity of the electrically conductive adhesive layer 308 may be enhanced by providing a conductive layer 305 between the electrically conductive adhesive layer 308 and the carrier 302. For example, the conductive layer 305 may comprise titanium and/or copper, or any other suitable electrically conductive material. Though, in some embodiments, the conductive layer 305 may be omitted when the electrically conductive adhesive layer 308 provides sufficient conductivity to drive the plating process. In an embodiment, the carrier 302 may comprise any suitable rigid material. In a particular embodiment, the carrier 302 may also comprise a glass layer.

Referring now to FIG. 3D, a cross-sectional illustration of the glass core 310 after a bottom-up plating process is used to form vias 320_{A} in the via openings 316 with the magnetic layer 335 and vias 320_{B} in the via openings 319 without the magnetic layer 335 is shown, in accordance with an embodiment. Since the only exposed conductive surfaces within the via openings 316 and 319 are the conductive adhesive layer 308 exposed at the bottom of the via openings 316 and 319, the vias 320_{A} and 320_{B} will plate up in a vertical direction. The bottom-up plating process may comprise an electroplating process or the like. In an embodiment, the vias 320_{A} and 320_{B} may have overburden that extends above the top surface 311 of the glass core 310.

Similar to other embodiments described herein, the vias 320_{A} and 320_{B} may have a textured outer surface that provides direct contact with the sidewalls of the via openings 316 and 319 at some locations and gaps between the vias 320_{A} and 320_{B} and the sidewalls of the magnetic layer 335 or the via openings 319 at other locations. Particularly, vias 320_{A} may directly contact portions of the sidewalls 333 of the magnetic layers 335, and vias 320_{B} may directly contact portions of the sidewalls 313 of the via openings 319 since there are no seed layer along the sidewalls 313 of the via openings 319 or along the sidewalls 333 of the magnetic layers 335. Further, the composition of the vias 320_{A} and 320_{B} may be substantially uniform since there is no seed layer within the via openings 319 or along the magnetic layer 335.

The profile of the sidewalls of the vias 320_{A} and 320_{B} may be similar to the profile of sidewalls 224 of the vias 220 described in greater detail herein. For example, a cross-sectional area of the vias 320_{A} and 320_{B} along a plane may be smaller than a cross-sectional area of the via openings 316 along the same plane. Accordingly, less stress induced into the glass core 310 during thermal cycling, and the glass core 310 is more robust than previous solutions.

Referring now to FIG. 3E, a cross-sectional illustration of the glass core 310 after the overburden of the vias 320_{A} and 320_{B} is removed is shown, in accordance with an embodiment. In an embodiment, the overburden may be removed with a polishing or planarizing process. For example, a chemical mechanical polishing (CMP) process may be used to remove the overburden.

Referring now to FIG. 3F, a cross-sectional illustration of the glass core 310 after the carrier 302 is removed is shown, in accordance with an embodiment. In an embodiment, the carrier 302 may be removed with any suitable process. For example, the carrier 302 may be removed by a thermal debonding process, a laser debonding process, a UV debonding process, or the like. Removal of the carrier 302 may expose a surface of the conductive layer 305.

Referring now to FIG. 3G, a cross-sectional illustration of the glass core 310 after the conductive layer 305 and the electrically conductive adhesive layer 308 are removed is shown, in accordance with an embodiment. In an embodiment, the conductive layer 305 may be removed with chemical etching process (e.g., a wet etching process) or a laser spallation process. In an embodiment, the electrically conductive adhesive layer 308 may be removed with a cleaning process or any other suitable process.

Referring now to FIG. 3H, a cross-sectional illustration of a package substrate 350 that comprises the glass core 310 is shown, in accordance with an embodiment. In an embodiment, the glass core 310 may be covered by a top buildup layer 351 over the top surface 311 and a bottom buildup layer 352 over the bottom surface 312 of the glass core 310. In an embodiment, the top buildup layer 351 and the bottom buildup layer 352 may each comprise a plurality of laminated organic layers (e.g., buildup film layers). In an embodiment, electrically conductive routing (not shown) within the top buildup layer 351 and the bottom buildup layer 352 may electrically couple the vias 320_{A} and/or 320_{B} to first level interconnects (FLIs) 354 and second level interconnects (SLIs) 353. The electrically conductive routing may include pads, traces, vias, and/or the like. In an embodiment, one or more dies 355 may be electrically coupled to the top buildup layer 351 by the FLIs 354. In some embodiments, a bridge substrate (not shown) that is embedded within the top buildup layer 351 or provided over the top buildup layer 351 may electrically couple two or more dies 355 together.

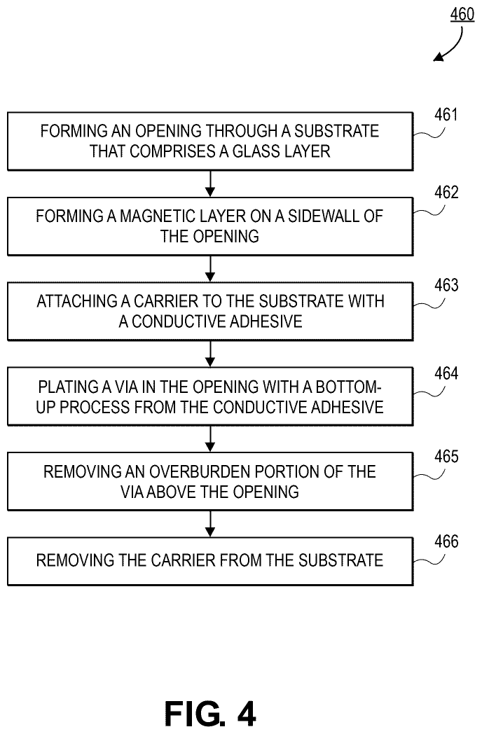

Referring now to FIG. 4, a flow diagram that depicts a process 460 for forming PMVs in a glass core with a bottom-up plating process is shown, in accordance with an embodiment. In an embodiment, the process 460 may be similar to the any of the bottom-up plating processes described in greater detail. For example, the PMVs may have vias with a textured surface that reduces stress generation in the glass core due to CTE mismatch issues.

In an embodiment, the process 460 may begin with operation 461, which comprises forming an opening through a substrate that comprises a glass layer. In an embodiment, the substrate may be similar to any of the glass cores described in greater detail herein. In an embodiment, the opening may be considered a via opening. The opening may be formed with any suitable patterning process, such as a laser assisted etching process or the like.

In an embodiment, the process 460 may continue with operation 462, which comprises forming a magnetic layer on a sidewall of the opening. In an embodiment, the magnetic layer may comprise one or more of iron, cobalt, or nickel. In some instances, a seed layer may be provided between the magnetic layer and the substrate.

In an embodiment, the process 460 may continue with operation 463, which comprises attaching a carrier to the substrate with a conductive adhesive. In an embodiment, the conductive adhesive may comprise an ECA or an ACF. In some embodiments, a conductive layer may be provided between the conductive adhesive and the carrier in order to improve the electrical conductivity of the conductive adhesive. For example, a layer comprising titanium and/or copper may be provided between the conductive adhesive and the carrier. The carrier may be a glass substrate or any other suitable rigid substrate material.

In an embodiment, the process 460 may continue with operation 464, which comprises plating a via in the opening with a bottom-up process from the conductive adhesive. For example, the conductive adhesive may span the opening, and the exposed portion of the conductive adhesive can be used as a seed layer to plate up the via. This allows for the via to be plated so that the opening is filled from bottom to top. Similar to other embodiments described herein, the plated via may have a textured surface that allows for the formation of submicron sized gaps between an edge of the via and the sidewall of the magnetic layer. Accordingly, the mechanical coupling is reduced, and stress induced by CTE mismatches between the via and the substrate are minimized. As such, reliability of the substrate is improved.

In an embodiment, the process may continue with operation 465, which comprises removing an overburden portion of the via above the opening. For example, a polishing process may be used to remove the overburden that is formed above a top surface of the substrate opposite from the carrier. For example, a CMP process may be used in some embodiments.

In an embodiment, the process 460 may continue with operation 466, which comprises removing the carrier from the substrate. In an embodiment, the carrier may be removed with any suitable debonding process, such as a laser debonding process, a thermal debonding process, a UV debonding process, or the like. After the carrier is removed, the conductive adhesive and any optional conductive layers may be removed as well. For example, an etching process, a polishing process, and/or a cleaning process may be used to remove the conductive adhesive and/or the conductive layer.

In an embodiment, the resulting substrate may then be integrated into a package substrate through typical buildup layer manufacturing processes. For example, a plurality of laminated layers are patterned to form electrical routing. The electrical routing in the buildup layers may electrically couple the via to a die coupled to the package substrate in some embodiments.

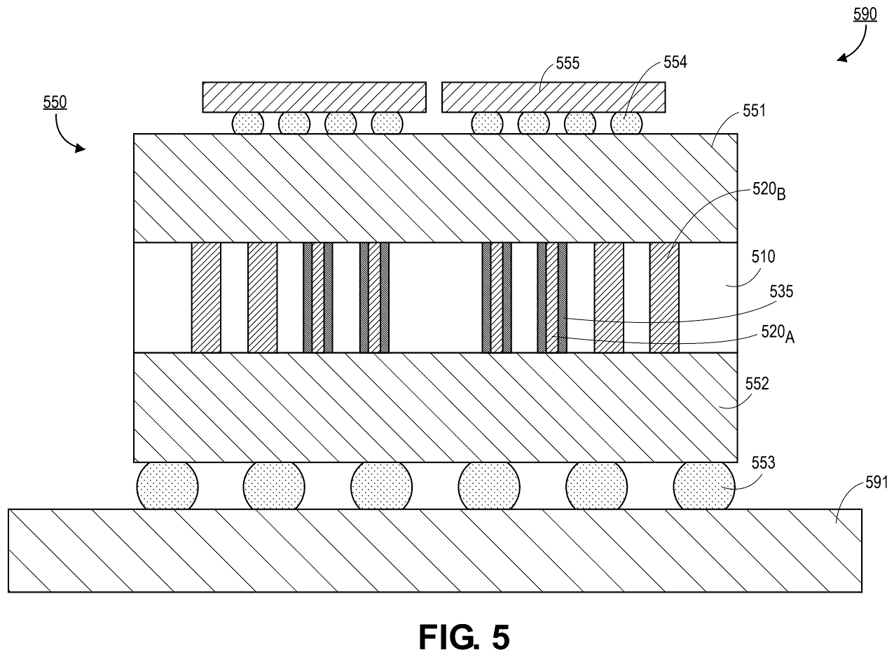

Referring now to FIG. 5, a cross-sectional illustration of an electronic system 590 is shown, in accordance with an embodiment. In an embodiment, the electronic system 590 may comprise a board 591, such as a printed circuit board (PCB), a motherboard, or the like. In an embodiment, the board 591 may be coupled to a package substrate 550 by SLIs 553. In an embodiment, the SLIs 553 may comprise solder balls, sockets, or the like.

In an embodiment, the package substrate 550 may be similar to any of the package substrates described in greater detail herein. In an embodiment, the package substrate 550 may comprise a glass core 510 with vias 520_{A} and 520_{B}. The vias 520_{A} and 520_{B} may be formed with a bottom-up plating process such as any of those described in greater detail herein. In an embodiment, the vias 520_{A} and 520_{B} may have textured surfaces that allow for a reduction in an amount of stress that is induced in the glass core 510 due to weaker mechanical coupling compared to existing plating processes. The vias 520_{A} and 520_{B} may be similar to any of the vias described in greater detail herein. For example, the vias 520_{A} may be part of a PMV with a magnetic layer 535 that surrounds the via 520_{A}. In an embodiment, the package substrate 550 may also comprise buildup layers 551 and 552 that are provided over and under the glass core 510.

In an embodiment, one or more dies 555 may be coupled to the buildup layer 551 by FLIs 554. The FLIs 554 may be any suitable FLI architecture, such as solder balls, copper bumps, hybrid bonding interfaces, or the like. In an embodiment, the one or more dies 555 may be any type of die (e.g., a processor die (e.g., a central processing unit (CPU), a graphics processing unit (GPU), an XPU), a memory die, a communications die, a power management die, and/or the like). In an embodiment, two or more dies 555 may be electrically coupled together by a bridge (not shown) that is embedded in the buildup layer 551 or provided over the buildup layer 551.

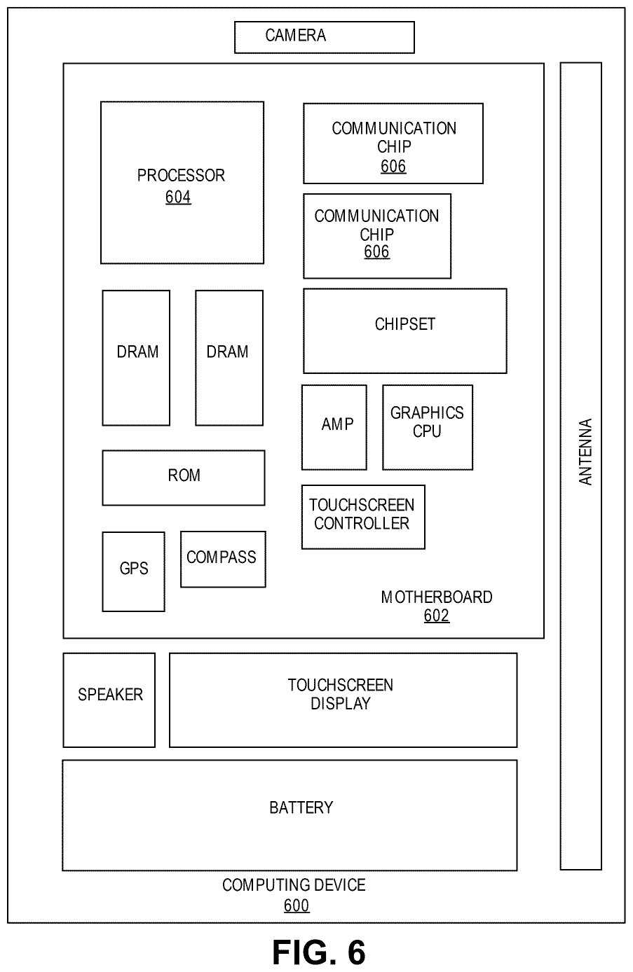

FIG. 6 illustrates a computing device 600 in accordance with one implementation of the disclosure. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604. In an embodiment, a device package is coupled to the board 602. One or both of the processor 604 or the communication chip 606 may be coupled to the board 602 through the device package.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the disclosure, the integrated circuit die of the processor may be part of a package substrate with a glass core that comprises PMVs that are formed with a bottom-up plating process, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the disclosure, the integrated circuit die of the communication chip may be part of a package substrate with a glass core that comprises PMVs that are formed with a bottom-up plating process, in accordance with embodiments described herein.

In an embodiment, the computing device 600 may be part of any apparatus. For example, the computing device may be part of a personal computer, a server, a mobile device, a tablet, an automobile, or the like. That is, the computing device 600 is not limited to being used for any particular type of system, and the computing device 600 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

### EXAMPLES

Example 1: an apparatus, comprising: a substrate, wherein the substrate comprises a glass layer; an opening through a thickness of the substrate; a layer over a sidewall of the opening, wherein the layer comprises a magnetic material; and a via in the opening, wherein the via directly contacts the layer at a first location, wherein a gap is provided between the via and the layer at a second location, and wherein the via is electrically conductive.

Example 2: the apparatus of Example 1, wherein a via sidewall is non-linear.

Example 3: the apparatus of Example 1 or Example 2, wherein the layer is separated from the sidewall of the opening by an electrically conductive seed layer.

Example 4: the apparatus of Example 3, wherein the electrically conductive seed layer comprises ruthenium.

Example 5: the apparatus of Examples 1-4, wherein the magnetic material comprise one or more of iron, cobalt, or nickel.

Example 6: the apparatus of Examples 1-5, wherein a composition of the via is substantially uniform across a line from a first edge of the via to a second edge of the via that is parallel to a top surface and/or a bottom surface of the substrate.

Example 7: the apparatus of Example 6, wherein the composition comprises substantially copper.

Example 8: the apparatus of Examples 1-7, wherein an aspect ratio (height:width) of the opening is approximately 10:1 or greater.

Example 9: the apparatus of Examples 1-8, wherein the gap has a width that is up to one micron.

Example 10: the apparatus of Examples 1-9, wherein the substrate is a core of a package substrate.

Example 11: an apparatus, comprising: a substrate, wherein the substrate comprises a glass layer; a first opening through a thickness of the substrate; a layer over a first sidewall of the first opening, wherein the layer comprises a magnetic material; a first via in the first opening, wherein the first via directly contacts the layer at a first location, wherein a first gap is provided between the first via and the layer at a second location, and wherein the first via is electrically conductive; a second opening through a thickness of the substrate; and a second via in the second opening, wherein the second via directly contacts a second sidewall of the second opening at a third location, wherein a second gap is provided between the second via and the second sidewall at a fourth location, and wherein the second via is electrically conductive.

Example 12: the apparatus of Example 11, wherein a third sidewall of the first via is non-linear.

Example 13: the apparatus of Example 11 or Example 12, wherein the layer is separated from the first sidewall of the first opening by an electrically conductive seed layer.

Example 14: the apparatus of Examples 11-13, wherein the magnetic material comprise one or more of iron, cobalt, or nickel.

Example 15: the apparatus of Examples 11-14, wherein the first via is part of a coaxial inductor integrated into the substrate.

Example 16: the apparatus of Examples 11-15, wherein the substrate is a core of a package substrate.

Example 17: the apparatus of Example 16, further comprising: a die coupled to the package substrate; and a board coupled to the package substrate.

Example 18: a method, comprising: forming a magnetic layer on a sidewall of an opening through a glass substrate; attaching a carrier to the glass substrate with a conductive adhesive, wherein the conductive adhesive spans across the opening through the glass substrate; plating a via in the opening with a bottom-up process from the conductive adhesive, wherein the via is separated from the glass substrate by the magnetic layer; and removing the carrier from the glass substrate.

Example 19: the method of Example 18, wherein the via directly contacts a sidewall of the magnetic layer at a first location of the magnetic layer, and wherein the via is spaced away from the magnetic layer by a gap at a second location of the magnetic layer.

Example 20: the method of Example 18 or Example 19, further comprising a layer comprising titanium and/or copper between the conductive adhesive and the carrier.

What is claimed is:

1. An apparatus, comprising:
a substrate, wherein the substrate comprises a glass layer;
an opening through a thickness of the substrate;
a layer over a sidewall of the opening, wherein the layer comprises a magnetic material; and
a via in the opening, wherein the via directly contacts the layer at a first location, wherein a gap is provided between the via and the layer at a second location, and wherein the via is electrically conductive.

2. The apparatus of claim 1, wherein a via sidewall is non-linear.

3. The apparatus of claim 1, wherein the layer is separated from the sidewall of the opening by an electrically conductive seed layer.

4. The apparatus of claim 3, wherein the electrically conductive seed layer comprises ruthenium.

5. The apparatus of claim 1, wherein the magnetic material comprise one or more of iron, cobalt, or nickel.

6. The apparatus of claim 1, wherein a composition of the via is substantially uniform across a line from a first edge of the via to a second edge of the via that is parallel to a top surface and/or a bottom surface of the substrate.

7. The apparatus of claim 6, wherein the composition comprises substantially copper.

8. The apparatus of claim 1, wherein an aspect ratio (height:width) of the opening is approximately 10:1 or greater.

9. The apparatus of claim 1, wherein the gap has a width that is up to one micron.

10. The apparatus of claim 1, wherein the substrate is a core of a package substrate.

11. An apparatus, comprising:
a substrate, wherein the substrate comprises a glass layer;
a first opening through a thickness of the substrate;
a layer over a first sidewall of the first opening, wherein the layer comprises a magnetic material;
a first via in the first opening, wherein the first via directly contacts the layer at a first location, wherein a first gap is provided between the first via and the layer at a second location, and wherein the first via is electrically conductive;
a second opening through a thickness of the substrate; and
a second via in the second opening, wherein the second via directly contacts a second sidewall of the second opening at a third location, wherein a second gap is provided between the second via and the second sidewall at a fourth location, and wherein the second via is electrically conductive.

12. The apparatus of claim 11, wherein a third sidewall of the first via is non-linear.

13. The apparatus of claim 11, wherein the layer is separated from the first sidewall of the first opening by an electrically conductive seed layer.

14. The apparatus of claim 11, wherein the magnetic material comprise one or more of iron, cobalt, or nickel.

15. The apparatus of claim 11, wherein the first via is part of a coaxial inductor integrated into the substrate.

16. The apparatus of claim 11, wherein the substrate is a core of a package substrate.

17. The apparatus of claim 16, further comprising:
a die coupled to the package substrate; and
a board coupled to the package substrate.

18. A method, comprising:
forming a magnetic layer on a sidewall of an opening through a glass substrate;
attaching a carrier to the glass substrate with a conductive adhesive, wherein the conductive adhesive spans across the opening through the glass substrate;
plating a via in the opening with a bottom-up process from the conductive adhesive, wherein the via is separated from the glass substrate by the magnetic layer; and
removing the carrier from the glass substrate.

19. The method of claim 18, wherein the via directly contacts a sidewall of the magnetic layer at a first location of the magnetic layer, and wherein the via is spaced away from the magnetic layer by a gap at a second location of the magnetic layer.

20. The method of claim 18, further comprising a layer comprising titanium and/or copper between the conductive adhesive and the carrier.
